(19) United States
(12) Patent Application Publication
(10) Pub. No.: US 2025/0273541 A1
(43) Pub. Date: Aug. 28, 2025

(54) INTERDIGITATED CANTILEVER LEAD FRAME IN CHIP-ON-LEAD PACKAGE DESIGN

(71) Applicant: Texas Instruments Incorporated, Dallas, TX (US)

(72) Inventors: Yu Yang, Chengdu (CN); Chin Sern Alex Ting, Ipoh (CN); Xi Lin Li, Chengdu (CN); Silijia Xie, Kunming (CN); Yuntao Xu, Chengdu (CN)

(21) Appl. No.: 18/589,044

(22) Filed: Feb. 27, 2024

(51) Int. Cl. H01L 23/495; H01L 23/00; H01L 23/31

(52) U.S. Cl. CPC H01L 23/49541; H01L 23/3107; H01L 24/32; H01L 24/48; H01L 24/73; H01L 24/83; H01L 24/85; H01L 24/92; H01L 2224/32245; H01L 2224/48245; H01L 2224/73265; H01L 2224/83; H01L 2224/85203; H01L 2224/85205; H01L 2224/85207; H01L 2224/92247

(57) ABSTRACT

A semiconductor package has a chip-on-lead configuration with leads that are cantilevered and interdigitated. The leads extend from contact surfaces on opposite sides of the semiconductor package to support locations under a semiconductor die that is attached to the leads. The contact surfaces are exposed at a bottom surface of the semiconductor package, adjacent to a perimeter of the semiconductor package. The leads from opposite sides of the semiconductor package extend past each other under the die. The cantilevered leads do not extend to the bottom surface under the semiconductor die. The semiconductor package includes electrical connections from the semiconductor die to the leads. The semiconductor package is formed by attaching the semiconductor die to the leads, followed by forming the electrical connections.

### TECHNICAL FIELD

This disclosure relates to the field of semiconductor packages. More particularly, but not exclusively, this disclosure relates to chip-on-lead semiconductor packages.

### BACKGROUND

Chip-on-lead quad flat no lead (QFN) semiconductor packages have semiconductor die attached to leads, rather than die pads. The chip-on-lead configuration provides smaller footprints compared to packages with die pads.

### SUMMARY

The present disclosure introduces a semiconductor package having a chip-on-lead configuration with two leads that are cantilevered and interdigitated. The leads extend from contact surfaces on opposite sides of the semiconductor package. A semiconductor die is attached to the leads. The leads extend past each other under the die. The leads are not exposed at a bottom surface of the semiconductor package under the semiconductor die. The semiconductor package includes electrical connections from the semiconductor die to each of the leads. The semiconductor package is formed by attaching the semiconductor die to the leads. The contact surfaces extend downward farther than the leads under the semiconductor die. The electrical connections are formed after the semiconductor die is attached to the leads.

### BRIEF DESCRIPTION OF THE VIEWS OF THE DRAWINGS

FIG. 1A through FIG. 1I depict an example semiconductor package having cantilevered interdigitated leads, in stages of an example method of formation.

FIG. 2A through FIG. 2G depict another example semiconductor package having cantilevered interdigitated leads, in stages of another example method of formation.

FIG. 3A, a top view, and FIG. 3B, a cross section, depict a further example semiconductor package having cantilevered interdigitated leads.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

A semiconductor package includes a semiconductor die and has a chip-on-lead configuration, that is, the semiconductor die partially overlaps leads of the semiconductor package and is attached to the leads through a die attach material. The leads include a first lead that extends from a first contact surface adjacent to a first side of the semiconductor package to a first support location under the semiconductor die. The leads include a second lead that extends from a second contact surface adjacent to a second side of the semiconductor package, opposite from the first side, to a second support location under the semiconductor die. The first contact surface and the second contact surface are exposed through an encapsulation material, which is electrically non-conductive, at a bottom surface of the semiconductor package.

The first lead and the second lead are cantilevered, that is, the first lead and the second lead do not extend to a bottom surface of the semiconductor package under the semiconductor die. The first contact surface does not extend under the semiconductor die; the second contact surface does not extend under the semiconductor die. The cantilevered configuration, with electrically non-conductive encapsulation material under cantilevered portions of the leads, may advantageously enable placement of the semiconductor package on a circuit substrate, such as a printed circuit board, with conductors between the contact surfaces.

The two leads are interdigitated, that is, the first lead extends past the second lead under the semiconductor die. In terms of the support locations, a distance between the first support location and the first side of the semiconductor package is greater than a distance between the second support location and the first side of the semiconductor package. Correspondingly, a distance between the second support location and the second side of the semiconductor package is greater than a distance between the first support location and the second side of the semiconductor package.

The semiconductor package includes electrical connections from the semiconductor die to each of the first lead and the second lead. The electrical connections may be implemented as wire bonds. The chip-on-lead configuration may advantageously enable a smaller area for the semiconductor package by enabling the electrical connections at the leads to be placed closer to the semiconductor die than would be practical for a semiconductor package having a die pad.

The interdigitated configuration of the first lead and the second lead may support the semiconductor die during formation of the electrical connections at the semiconductor die to provide more reliability for the semiconductor package, compared to packages with cantilevered leads that are not interdigitated.

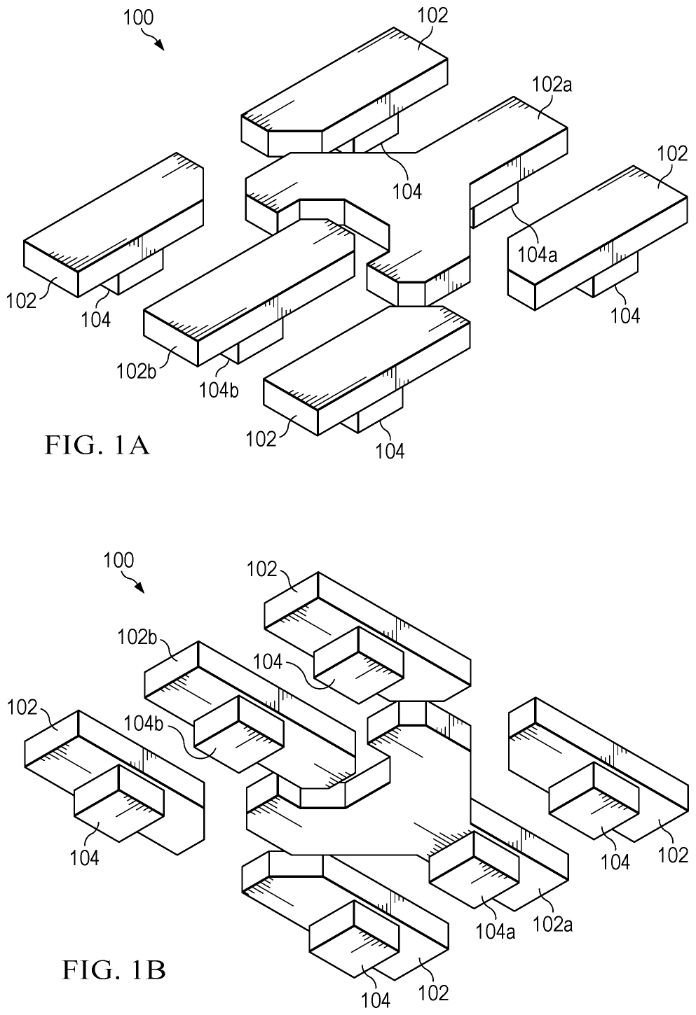

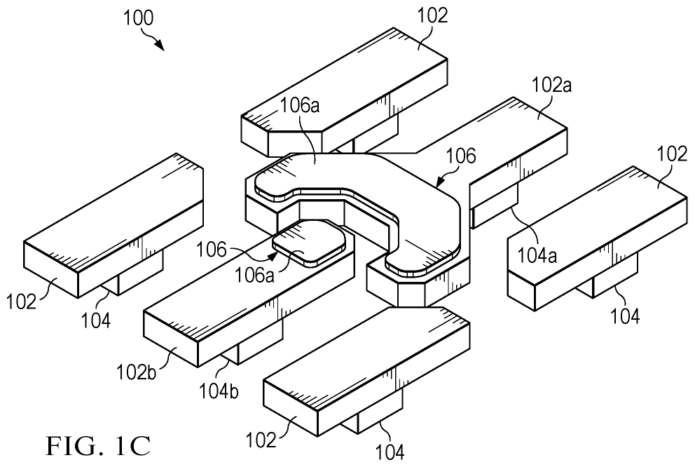

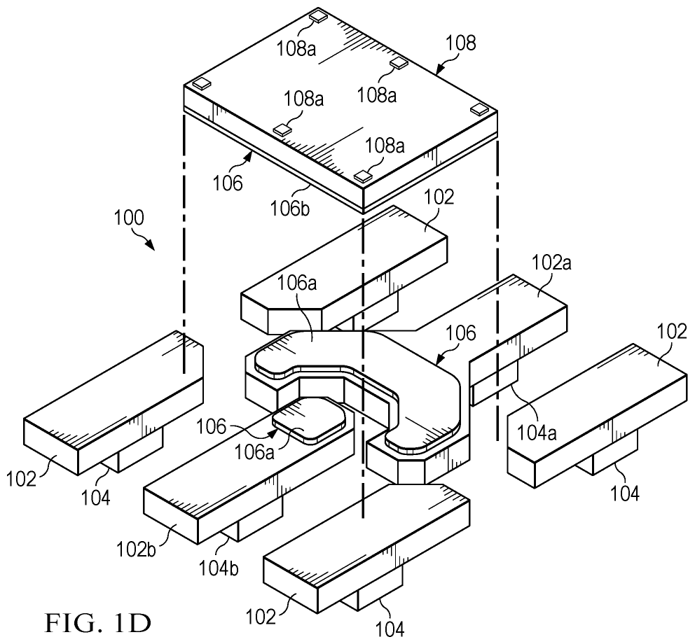

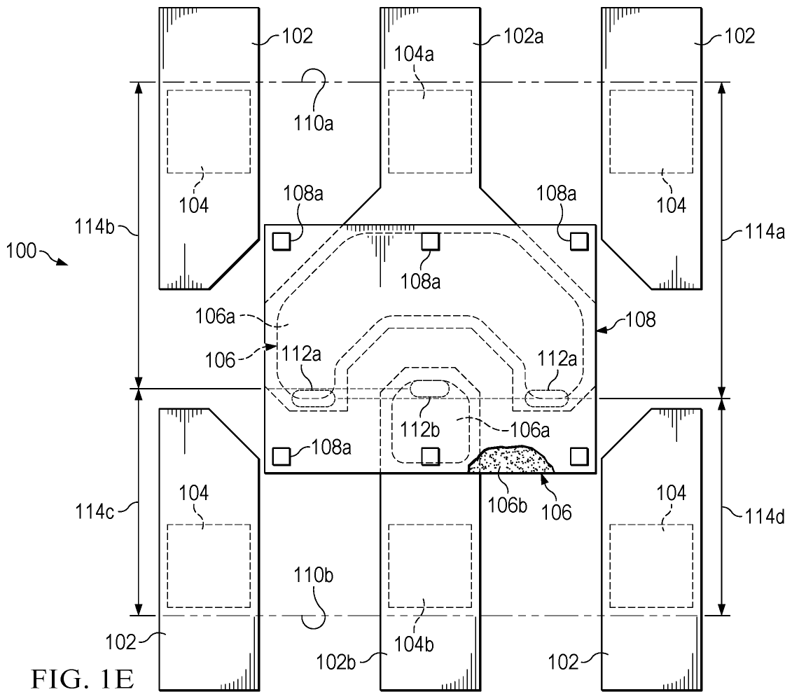

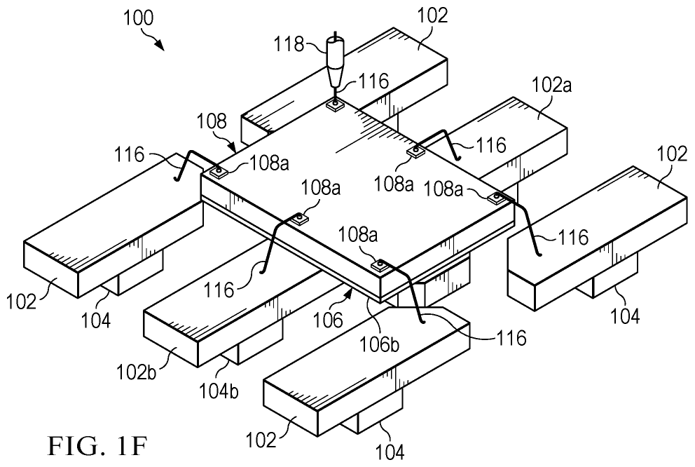

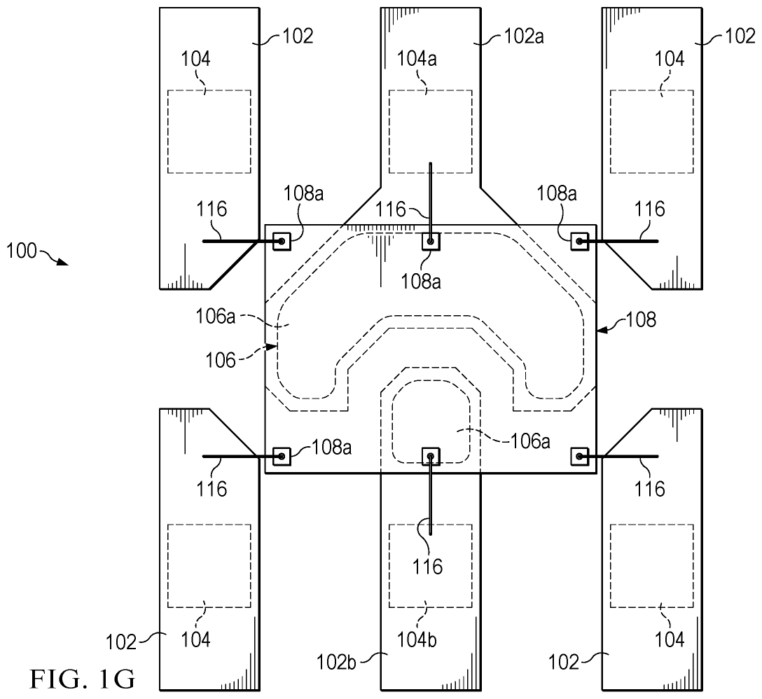

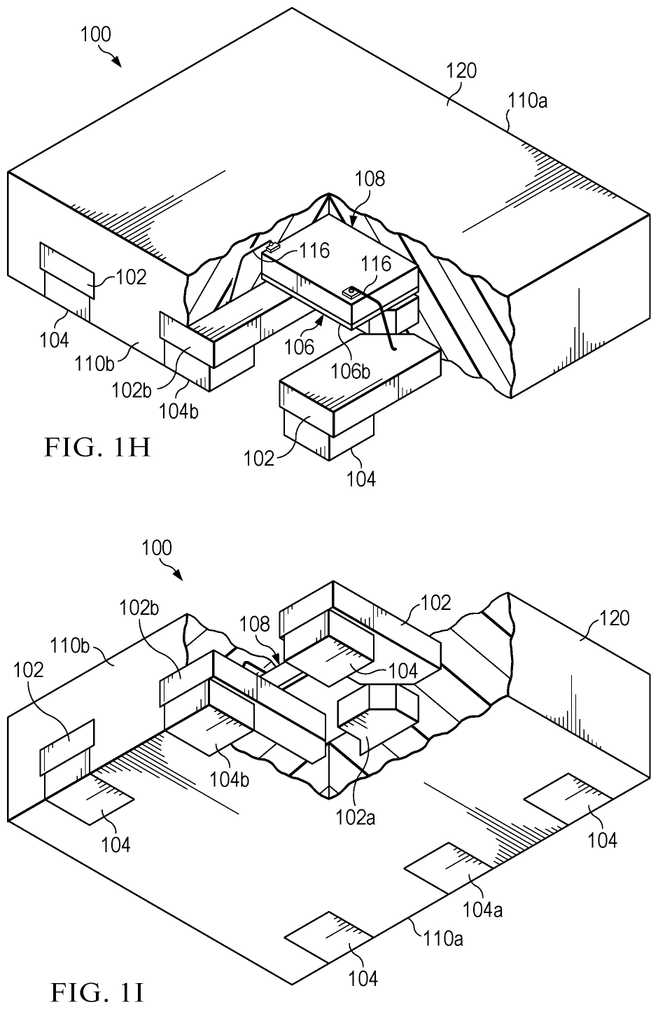

FIG. 1A through FIG. 1I depict an example semiconductor package having cantilevered interdigitated leads, in stages of an example method of formation. FIG. 1A is a top perspective view and FIG. 1B is a bottom perspective view of the leads of the semiconductor package. Referring to FIG. 1A and FIG. 1B, the semiconductor package 100 includes leads 102. The leads 102 may be parts of a lead frame that has additional leads for additional semiconductor packages, not specifically shown. The leads 102 include a first lead 102a and a second lead 102b. Each of the leads 102 includes a contact surface 104 at a bottom of the corresponding lead 102. The first lead has a first contact surface 104a, and the second lead 102b has a second contact surface 104b. The contact surfaces 104 are located in a plane lower than the rest of the leads 102.

Referring to FIG. 1C, which is a top perspective view, a first die attach part 106a of a die attach material 106 is formed on the first lead 102a and the second lead 102b. In this example, the first die attach part 106a may be implemented as die attach paste 106a. The die attach paste 106a may include epoxy, by way of example. The first die attach part 106a may be formed on the first lead 102a and the second lead 102b by a dispense process, by way of example. The first die attach part 106a may include metal particles, such as silver particles or nickel-plated copper particles, which may advantageously improve adhesion to the first and second leads 102a and 102b, compared to an unfilled die attach paste.

Referring to FIG. 1D, a semiconductor die 108 and a second die attach part 106b of the die attach material 106 are attached to the leads 102 through the first die attach part 106a of the die attach material 106. In this example, the second die attach part 106b may be implemented as a die attach film 106b attached to a bottom surface of the semiconductor die 108. The die attach film 106b may advantageously improve adhesion to the semiconductor die 108, compared to die attach paste. The die attach film 106b may be singulated with the semiconductor die 108, so that a perimeter of the die attach film 106b is coterminous with a perimeter of the semiconductor die 108, as depicted in FIG. 1D. Alternatively, die attach part 106a or die attach film 106b may be omitted.

The semiconductor die 108 may be implemented as an integrated circuit, a discrete transistor, a micro electrical mechanical system (MEMS) device, an electro-optical device, or a microfluidic device, by way of example. Other manifestations of the semiconductor die 108 are within the scope of this example. The semiconductor die 108 partially overlaps the first and second leads 102a and 102b, providing a chip-on-lead configuration for the semiconductor package 100. The semiconductor die 108 may include bond pads 108a on a top surface, opposite from the bottom surface.

Referring to FIG. 1E, which is a top view of the semiconductor package 100, the first lead 102a extends from the first contact surface 104a, adjacent to a first side 110a of the semiconductor package 100, to first support locations 112a under the semiconductor die 108. The semiconductor die 108 is attached to the first lead 102a at the first support locations 112a by the die attach material 106. The second lead 102b extends from the second contact surface 104b, adjacent to a second side 110b of the semiconductor package 100, opposite from the first side, to a second support location 112b under the semiconductor die 108. The semiconductor die 108 is attached to the second lead 102b at the second support location 112b by the die attach material 106. In this example, the first lead 102a is thicker over the first contact surface 104a than under the semiconductor die 108, and the second lead 102b is thicker over the second contact surface 104b than under the semiconductor die 108. The semiconductor die 108 is located over cantilevered portions of the first lead 102a and the second lead 102b.

The first lead 102a and the second lead 102b are interdigitated, that is, the first lead 102a extends past the second lead 102b under the semiconductor die. In one aspect, a first distance 114a between the first support locations 112a and the first side 110a of the semiconductor package 100 may be greater than a second distance 114b between the second support location 112b and the first side 110a of the semiconductor package 100. A third distance 114c between the second support location 112b and the second side 110b may be greater than a fourth distance 114d between the first support locations 112a and the second side 110b. In another aspect, the first support locations 112a may be closer to the second contact surface 104b than they are to the first contact surface 104a, and the second support location 112b may be closer to the first contact surface 104a than it is to the second contact surface 104b.

Referring to FIG. 1F, which is a perspective view of the semiconductor package 100, electrical connections 116 are formed between the bond pads 108a of the semiconductor die 108 and the leads 102. The electrical connections 116 may be manifested as wire bonds 116, formed by a wire bond process using a wire bond tool 118, with ball bonds on the bond pads 108a and stitch bonds on the leads 102, as depicted in FIG. 1F. The die attach paste 106a, obscured in FIG. IF by the die attach film 106b and the semiconductor die 108, may be recessed from the perimeter of the semiconductor die 108 to allow for resin bleed on the leads 102, enabling placement of the stitch bonds close to the semiconductor die 108, advantageously providing a reduced area of the semiconductor package 100. The wire bond process may be implemented as an ultrasonic wire bond process, a thermocompression wire bond process, or an ultrasonic thermocompression wire bond process, by way of example. Other types of electrical connections, such as ribbon bonds or clip bonds, are within the scope of this example. In this example, the first lead 102a and the second lead 102b are not contacted directly below the semiconductor die 108 by elements of the wire bond tool 118 forming the electrical connections 116. The interdigitated configuration of the first lead 102a and the second lead 102b may advantageously provide more support to the semiconductor die 108 during formation of the electrical connections 116 to the bond pads 108a.

Referring to FIG. 1G, which is a top view of the semiconductor package 100, the electrical connections 116 to the semiconductor die 108 are located over cantilevered portions of the first lead 102a and the second lead 102b. The electrical connections 116 to the semiconductor die 108 may be located directly over a full thickness of the die attach material 106, including the die attach paste 106a, which may further improve support to the semiconductor die 108 during formation of the electrical connections 116 to the bond pads 108a.

Referring to FIG. 1H and FIG. 1I, which are perspective views of the semiconductor package 100, an encapsulation material 120 is formed on the leads 102 and the semiconductor die 108, surrounding the electrical connections 116. The encapsulation material 120 is electrically non-conductive. The encapsulation material 120 may include epoxy or benzocyclobutene (BCB), by way of example. The encapsulation material 120 may include dielectric particles, such as silicon dioxide or aluminum oxide, to reduce a thermal expansion coefficient of the encapsulation material 120, reducing stress on the semiconductor die 108. After the encapsulation material 120 is formed, the semiconductor package 100 is singulated, separating the leads 102 from the lead frame. The semiconductor package 100 may be singulated by a saw process, for example.

The encapsulation material 120 extends to a bottom surface of the semiconductor package 100, under the cantilevered portions of the leads 102. The contact surfaces 104 are exposed through the encapsulation material 120 at the bottom surface of the semiconductor package 100. The first side 110a of the semiconductor package 100 is located at the bottom surface of the semiconductor package 100, adjacent to the first contact surface 104a. The second side 110b of the semiconductor package 100 is located at the bottom surface of the semiconductor package 100, adjacent to the second contact surface 104b. Having the electrically non-conductive encapsulation material 120 under the cantilevered portions of the leads 102 may advantageously enable use of the semiconductor package 100 on a circuit substrate with conductors between the contact surfaces 104.

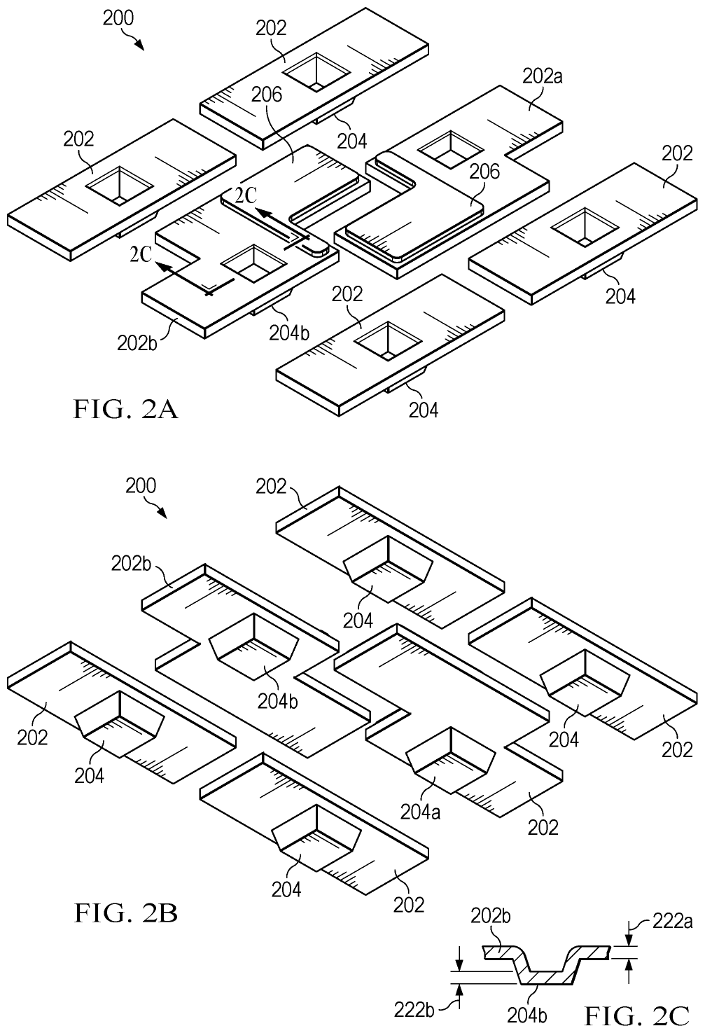

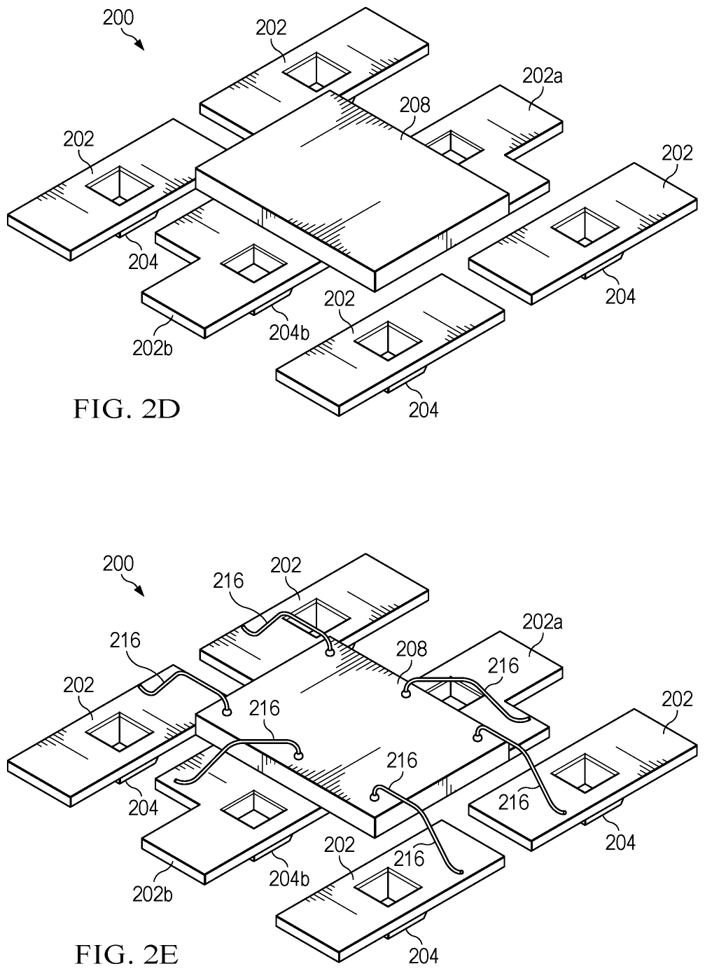

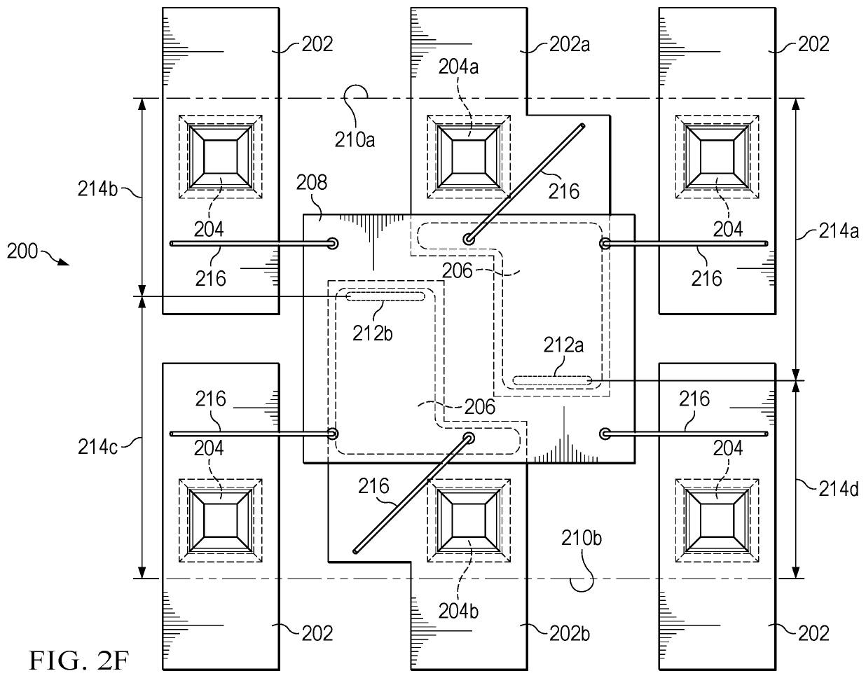

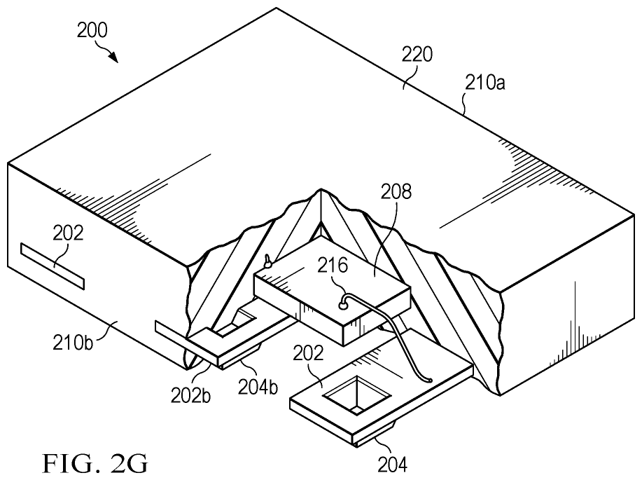

FIG. 2A through FIG. 2G depict another example semiconductor package having cantilevered interdigitated leads, in stages of another example method of formation. Referring to FIG. 2A, a top perspective view, and FIG. 2B, a bottom perspective view, the semiconductor package 200 includes leads 202, which may be parts of a lead frame. The leads 202 include a first lead 202a and a second lead 202b. Each of the leads 202 includes a contact surface 204 at a bottom of the corresponding lead 202. The first lead has a first contact surface 204a, and the second lead 202b has a second contact surface 204b. The contact surfaces 204 are located in a plane lower than the rest of the leads 202. The leads 202 of this example may be stamped from a sheet of copper, so that the top surfaces of the leads 202 are indented over the contact surfaces 204, as depicted in FIG. 2A and FIG. 2B.

A die attach material 206 is formed on the first lead 202a and the second lead 202b. In this example, the die attach material 206 may be implemented as die attach paste 206. The die attach paste 206 may have a composition as disclosed in reference to the die attach paste 106a of FIG. 1C.

FIG. 2C is a cross section of the second lead 202b through the second contact surface 204b. The second lead 202b has a top level thickness 222a extending to a top surface of the second lead 202b, and has a contact level thickness 222b over the second contact surface 204b. The top level thickness 222a may be substantially equal to the contact level thickness 222b, within tolerances encountered in stamping sheet metal, as a result of forming the leads 202 by stamping.

Referring to FIG. 2D, which is a perspective view, a semiconductor die 208 is attached to the first lead 202a and the second lead 202b through the die attach material 206. The die attach material 206 is subsequently cured. Using the die attach paste 206 may advantageously reduce a cost of the semiconductor package 200 compared to a more complex die attach material 206.

Referring to FIG. 2E, which is a perspective view, electrical connections 216 are formed between the semiconductor die 208 and the leads 202. The electrical connections 216 may be manifested as wire bonds 216. The interdigitated configuration of the first lead 202a and the second lead 202b may advantageously provide more support to the semiconductor die 208 during formation of the electrical connections 216 to the semiconductor die 208.

Referring to FIG. 2F, which is a top view of the semiconductor package 200, the first lead 202a extends from the first contact surface 204a, adjacent to a first side 210a of the semiconductor package 200, to a first support location 212a under the semiconductor die 208. The semiconductor die 208 is attached to the first lead 202a at the first support location 212a through the die attach material 206. The second lead 202b extends from a second contact surface 204b, adjacent to a second side 210b of the semiconductor package 200, opposite from the first side, to a second support location 212b under the semiconductor die 208. The semiconductor die 208 is attached to the second lead 202b at the second support location 212b through the die attach material 206. The semiconductor die 208 is located over cantilevered portions of the first lead 202a and the second lead 202b.

The first lead 202a and the second lead 202b are interdigitated, that is, the first lead 202a extends past the second lead 202b under the semiconductor die 208. In one aspect, a first distance 214a between the first support location 212a and the first side 210a of the semiconductor package 200 may be greater than a second distance 214b between the second support location 212b and the first side 210a of the semiconductor package 200. A third distance 214c between the second support location 212b and the second side 210b may be greater than a fourth distance 214d between the first support locations 212a and the second side 210b. In another aspect, the first support location 212a may be closer to the second contact surface 204b than it is to the first contact surface 204a, and the second support location 212b may be closer to the first contact surface 204a than it is to the second contact surface 204b.

The electrical connections 216 to the semiconductor die 208 are located over cantilevered portions of the first lead 202a and the second lead 202b. The electrical connections 216 to the semiconductor die 208 may be located directly over the die attach material 206, which may further improve support to the semiconductor die 208 during formation of the electrical connections 216 to the semiconductor die 208.

Referring to FIG. 2G, which is a perspective view of the semiconductor package 200, an encapsulation material 220, which is electrically non-conductive, is formed on the leads 202 and the semiconductor die 208, surrounding the electrical connections 216. After the encapsulation material 220 is formed, the semiconductor package 200 is singulated, separating the leads 202 from the lead frame. The encapsulation material 220 extends to a bottom surface of the semiconductor package 200, under the cantilevered portions of the leads 202. The contact surfaces 204 are exposed through the encapsulation material 220 at the bottom surface of the semiconductor package 200. The first side 210a of the semiconductor package 200 is located at the bottom surface of the semiconductor package 200, adjacent to the first contact surface 204a. The second side 210b of the semiconductor package 200 is located at the bottom surface of the semiconductor package 200, adjacent to the second contact surface 204b.

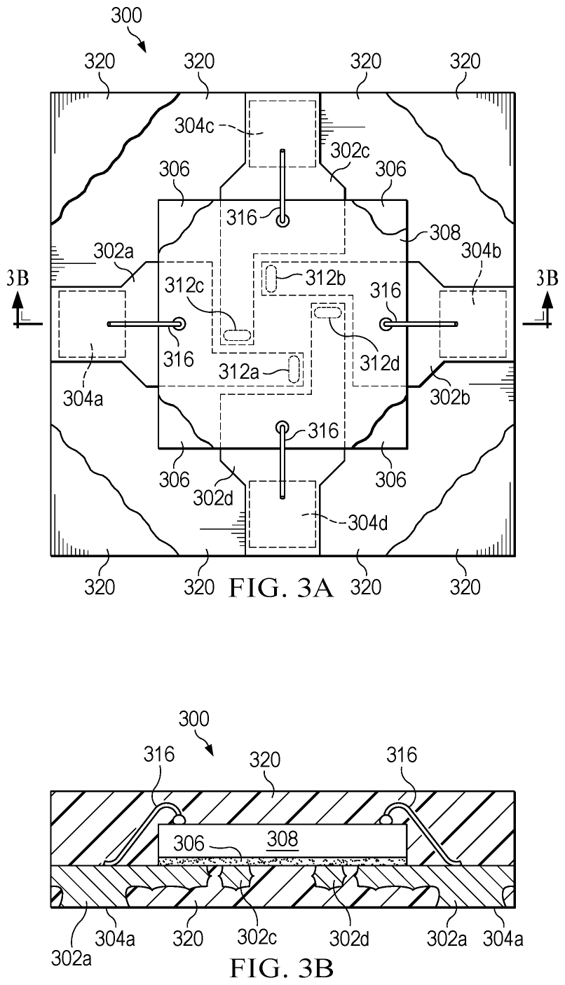

FIG. 3A, a top view, and FIG. 3B, a cross section, depict a further example semiconductor package having cantilevered interdigitated leads. Referring to FIG. 3A and FIG. 3B, the semiconductor package 300 of this example includes a first lead 302a, a second lead 302b, a third lead 302c, and a fourth lead 302d, which may be parts of a lead frame. The first lead 302a has a first contact surface 304a, the second lead 302b has a second contact surface 304b, the third lead 302c has a third contact surface 304c, the fourth lead 302d has a fourth contact surface 304d. The contact surfaces 304a through 304d are located in a plane lower than the rest of the leads 302a through 302d. The leads 302a through 302d of this example may be etched from a sheet of copper, as indicated in FIG. 3B.

A semiconductor die 308 is attached to the leads 302a through 302d through a die attach material 306. In this example, the die attach material 306 may be implemented as a die attach film 306 attached to a bottom surface of the semiconductor die 308. The die attach film 306 may advantageously provide improved adhesion to the semiconductor die 308. A perimeter of the die attach film 106b may be coterminous with the semiconductor die 308, as depicted in FIG. 3A and FIG. 3B.

The first lead 302a extends from the first contact surface 304a to a first support location 312a under the semiconductor die 308, and the second lead 302b extends from the second contact surface 304b, opposite from the first contact surface 304a, to a second support location 312b under the semiconductor die 308. Similarly, the third lead 302c extends from the third contact surface 304c to a third support location 312c under the semiconductor die 308, and the fourth lead 302d extends from the fourth contact surface 304d, opposite from the third contact surface 304c, to a fourth support location 312d under the semiconductor die 308. The semiconductor die 308 is attached to each of the leads 302a through 302d at the corresponding support locations 312a through 312d, respectively, by the die attach material 306.

The semiconductor die 308 is located over cantilevered portions of the leads 302a through 302d. The first lead 302a and the second lead 302b are interdigitated, that is, the first lead 302a extends past the second lead 302b under the semiconductor die 308. The first support location 312a may be closer to the second contact surface 304b than it is to the first contact surface 304a, and the second support location 312b may be closer to the first contact surface 304a than it is to the second contact surface 304b. Similarly, the third lead 302c and the fourth lead 302d are interdigitated, that is, the third lead 302c extends past the fourth lead 302d under the semiconductor die 308. The third support location 312c may be closer to the fourth contact surface 304d than it is to the third contact surface 304c, and the fourth support location 312d may be closer to the third contact surface 304c than it is to the fourth contact surface 304d.

Electrical connections 316 are formed between the semiconductor die 308 and the leads 302a through 302d. The electrical connections 316 may be manifested as wire bonds 316. The interdigitated configuration of the leads 302a through 302d may advantageously provide more support to the semiconductor die 308 during formation of the electrical connections 316. The die attach film 306 may reduce resin bleed compared to die past, enabling the electrical connections 316 to be placed closer to the semiconductor die 308, advantageously providing a smaller area for the semiconductor package 300.

An encapsulation material 320, which is electrically non-conductive, is formed on the leads 302a through 302d and the semiconductor die 308, surrounding the electrical connections 316. After the encapsulation material 320 is formed, the semiconductor package 300 is singulated, separating the leads 302a through 302d from the lead frame. The encapsulation material 320 extends to a bottom surface of the semiconductor package 300, under the cantilevered portions of the leads 302a through 302d. The contact surfaces 304a through 304d are exposed through the encapsulation material 320 at the bottom surface of the semiconductor package 300.

Various features of the examples disclosed herein may be combined in other manifestations of example semiconductor packages. For example, any of the semiconductor packages disclosed in reference to FIG. 1A through FIG. 1H, FIG. 2A through FIG. 2G, and FIG. 3A and FIG. 3B may have die attach material including die attach paste, die attach film, or a combination of die attach paste and die attach film. Any of the semiconductor packages disclosed in reference to FIG. 1A through FIG. 1H, FIG. 2A through FIG. 2G, and FIG. 3A and FIG. 3B may have leads that are thicker over the contact surfaces than in the cantilevered portions. Any of the semiconductor packages disclosed in reference to FIG. 1A through FIG. 1H, FIG. 2A through FIG. 2G, and FIG. 3A and FIG. 3B may have leads that have substantially equal thicknesses over the contact surfaces and in the cantilevered portions. Any of the semiconductor packages disclosed in reference to FIG. 1A through FIG. 1H, FIG. 2A through FIG. 2G, and FIG. 3A and FIG. 3B may have one pair of cantilevered interdigitated leads, or more than one pair of cantilevered interdigitated leads.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present disclosure should not be limited by any of the above described embodiments. Rather, the scope of the disclosure should be defined in accordance with the following claims and equivalents.

What is claimed is:

1. A semiconductor package, comprising:
a semiconductor die;
a first lead, extending from a first contact surface to a first support location under the semiconductor die, wherein:
the semiconductor die is attached to the first lead at the first support location;
the first contact surface is exposed at a bottom surface of the semiconductor package; and
the first lead is not exposed at the bottom surface of the semiconductor package under the semiconductor die;
a second lead, extending from a second contact surface to a second support location under the semiconductor die, wherein:
the semiconductor die is attached to the second lead at the second support location;
the second contact surface is exposed at the bottom surface of the semiconductor package, opposite from the first contact surface;
the second lead is not exposed at the bottom surface of the semiconductor package under the semiconductor die; and
the first lead and the second lead extend past each other under the semiconductor die;
a first electrical connection between the semiconductor die and the first lead; and
a second electrical connection between the semiconductor die and the second lead.

2. The semiconductor package of claim 1, wherein:
the first contact surface does not extend under the semiconductor die; and
the second contact surface does not extend under the semiconductor die.

3. The semiconductor package of claim 1, wherein the semiconductor die is located over cantilevered portions of the first lead and the second lead.

4. The semiconductor package of claim 1, wherein:
the first support location is closer to the second contact surface than the first support location is to the first contact surface; and
the second support location is closer to the first contact surface than the second support location is to the second contact surface.

5. The semiconductor package of claim 1, wherein:
a first distance between the first support location and a first side of the semiconductor package, adjacent to the first contact surface, is greater than a second distance between the second support location and the first side of the semiconductor package; and
a third distance between the second support location and a second side of the semiconductor package, adjacent to the second contact surface, is greater than a fourth distance between the first support location and the second side of the semiconductor package.

6. The semiconductor package of claim 1, wherein the semiconductor die is attached to the first lead and to the second lead by a die attach material selected from the group consisting of a die attach paste, a die attach film, and by a combination of a die attach film and a die attach paste.

7. The semiconductor package of claim 6, wherein the die attach material on the first lead and the die attach material on the second lead extend past each other under the semiconductor die.

8. The semiconductor package of claim 1, wherein the first electrical connection and the second electrical connection are wire bonds.

9. The semiconductor package of claim 1, further including electrically insulating package material between the first lead and the bottom surface of the semiconductor package, under the semiconductor die, and between the second lead and the bottom surface of the semiconductor package, under the semiconductor die.

10. A method of forming a semiconductor package, comprising:
attaching a semiconductor die to a first lead and a second lead, the first lead extending from a first contact surface to a first support location under the semiconductor die, the second lead extending from a second contact surface, opposite from the first contact surface, to a second support location under the semiconductor die, wherein the first contact surface and the second contact surface extend downward farther than the first lead and the second lead under the semiconductor die, and the first lead and the second lead extend past each other under the semiconductor die;
forming a first electrical connection from the semiconductor die to the first lead; and
forming a second electrical connection from the semiconductor die to the second lead.

11. The method of claim 10, wherein:
the first contact surface does not extend under the semiconductor die; and
the second contact surface does not extend under the semiconductor die.

12. The method of claim 10, wherein the semiconductor die is located over cantilevered portions of the first lead and the second lead.

13. The method of claim 10, wherein:
the first lead is thicker over the first contact surface than under the semiconductor die; and
the second lead is thicker over the second contact surface than under the semiconductor die.

14. The method of claim 10, wherein:
the first lead has a same thickness over the first contact surface and under the semiconductor die; and
the second lead has a same thickness over the second contact surface and under the semiconductor die.

15. The method of claim 10, wherein attaching the semiconductor die to the first lead and to the second lead includes dispensing a die attach paste onto the first lead and the second lead, and subsequently placing the semiconductor die on the die attach paste, followed by curing the die attach paste.

16. The method of claim 10, wherein attaching the semiconductor die to the first lead and to the second lead includes attaching a die attach film, that is attached to the semiconductor die, to the first lead and to the second lead, followed by curing the die attach film.

17. The method of claim 10, wherein attaching the semiconductor die to the first lead and to the second lead includes dispensing a die attach paste onto the first lead and the second lead, and subsequently placing a die attach film, that is attached to the semiconductor die, to the first lead and to the second lead, followed by curing the die attach film.

18. The method of claim 10, wherein forming the first electrical connection includes forming a wire ball bond to the semiconductor die.

19. The method of claim 18, wherein forming the wire ball bond is performed with a ball bond process selected from the group consisting of a thermocompression ball bond process, an ultrasonic ball bond process, and an ultrasonic thermocompression ball bond process.

20. The method of claim 10, wherein the first lead and the second lead are not contacted directly below the semiconductor die by equipment forming the first electrical connection and the second electrical connection.
